(19) United States
(12) Patent Application Publication
(10) Pub. No.: US 2022/0415713 A1
(43) Pub. Date: Dec. 29, 2022

(54) Metal Interconnects And Method Of Forming The Same

(71) Applicant: Taiwan Semiconductor Manufacturing Company, Ltd., Hsin-Chu (TW)

(72) Inventors: Han-Chung Lin, Hsinchu City (TW); Yen Chun Lin, Hsinchu City (TW); Chung-Yi Lin, Hsinchu County (TW); Bao-Ru Young, Hsinchu County (TW)

(21) Appl. No.: 17/726,705

(22) Filed: Apr. 22, 2022

Related U.S. Application Data
(60) Provisional application No. 63/214,650, filed on Jun. 24, 2021.

(51) Int. Cl. H01L 21/768; H01L 21/308; G06F 30/3953

(52) U.S. Cl. CPC H01L 21/76895; H01L 21/3086; G06F 30/3953

(57) ABSTRACT

A method of preparing a layout for manufacturing a semiconductor device includes receiving a layout that includes a plurality of metal interconnects, identifying a first set of metal interconnects from the metal interconnects corresponding to a first patterning process and a second set of metal interconnects from the metal interconnects corresponding to a second patterning process, identifying a first set of floating metal portions in the first set of metal interconnects and a second set of floating metal portions in the second set of metal interconnects, and removing the second set of floating metal portions from the layout, while the first set of floating metal portions remains in the layout.

### PRIORITY DATA

This application claims priority to U.S. Provisional Patent Application No. 63/214,650, filed on Jun. 24, 2021, entitled “Interconnect Structures and Method of Forming the Same”, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

One advancement in some IC design and fabrication has been the development of metal interconnects for high performance system-on-chip (SoC) applications. IC manufacturing process flow may be typically divided into three categories: front-end-of-line (FEOL) processes, middle-end-of-line (MEOL) processes, and back-end-of-line (BEOL) processes. FEOL processes generally encompass processes related to fabricating active IC devices, such as transistors. For example, FEOL processes may include forming isolation features, gate structures, and source/drain features. MEOL processes generally encompass processes related to fabricating contacts to features of the IC devices, such as contacts to the gate structures and/or the source/drain features. BEOL processes generally encompass processes related to fabricating interconnect structures that interconnects IC features fabricated at the FEOL level by way of contact formed at the MEOL level. Features fabricated by FEOL processes may be referred to as FEOL features. Features fabricated by MEOL processes may be referred to as MEOL features.

Features fabricated by BEOL processes may be referred to as BEOL features. In some embodiments, metal interconnects are fabricated at the BEOL level.

As ICs continue to scale down, a greater number of metal interconnects are arranged in a device area, increasing the density of interconnect structures in this area. For better process control, BEOL processes may adopt uniform pattern for forming metal lines in lower metal interconnect layers, such as metal 0 (M0) or metal 1 (M1) layers. However, uniform pattern also introduces large redundant parasitic capacitance, such as between two parallel metal lines. The parasitic capacitance causes circuit speed degradation. In one embodiment of the present disclosure, metal lines in lower metal interconnect layers, such as M0 metal lines or M1 metal lines, are formed uniformly by self-aligned double patterning (SADP) process. Subsequently, the process flow removes redundant portions of metal lines to achieve metal-to-metal parasitic capacitance reduction.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1A, 1B, and 1C illustrate layout views of metal interconnects in an integrated circuit, in accordance with one or more aspects of the present disclosure.

FIGS. 2, 3, 4, 5, 6, and 7 illustrate layout views of metal interconnects in an integrated circuit, in accordance with one or more aspects of the present disclosure.

FIG. 8 is a flow diagram of a method for forming a layout of metal interconnects in an integrated circuit, in accordance with one or more aspects of the present disclosure.

FIG. 9 illustrates an example computer system for implementing various embodiments of the present disclosure, in accordance with one or more aspects of the present disclosure.

FIG. 10 is a flow diagram of a method for forming a layout of metal interconnects based on a graphic database system (GDS) file, in accordance with one or more aspects of the present disclosure.

FIG. 11 is a flow diagram of a method for fabricating an interconnect layer with a layout of metal interconnects in an integrated circuit, in accordance with one or more aspects of the present disclosure.

FIGS. 12A, 13A, 14A, 15A, 16A, 17A, 18A, 19A, 20A, 21A, 22A, 23A, 24A, 25A, 26A, and 27A illustrate top views of an interconnect layer with a layout of metal interconnects in an integrated circuit at various stages of its fabrication process, in accordance with one or more aspects of the present disclosure.

FIGS. 12B, 13B, 14B, 15B, 16B, 17B, 18B, 19B, 20B, 21B, 22B, 23B, 24B, 25B, 26B, and 27B illustrate cross-sectional views of an interconnect layer with a layout of metal interconnects in an integrated circuit at various stages of its fabrication process, in accordance with one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Still further, when a number or a range of numbers is described with “about,” “approximate,” and the like, the term is intended to encompass numbers that are within +/−10% of the number described, unless otherwise specified. For example, the term “about 5 nm” encompasses the dimension range from 4.5 nm to 5.5 nm.

The present disclosure is generally related to design and fabrication of metal interconnects in a semiconductor device. As used herein, a semiconductor device refers to, for example, one or more transistors, integrated circuits, a semiconductor chip (e.g., memory chip, logic chip on a semiconductor die), a stack of semiconductor chips, a semiconductor package, a semiconductor wafer, and the like. Further, for reasons of clarity and consistency, similar elements appearing in figures are labeled the same, unless mentioned otherwise.

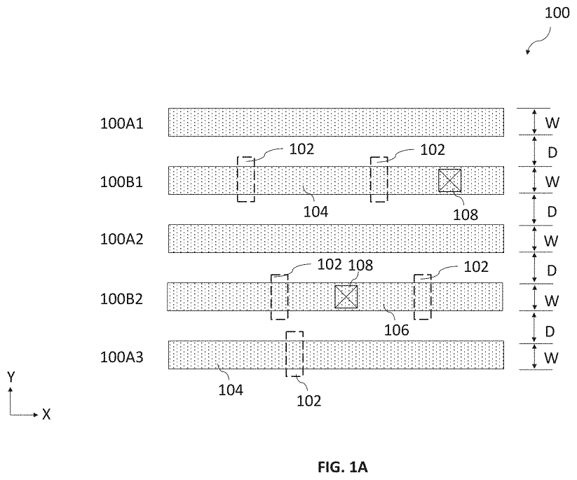

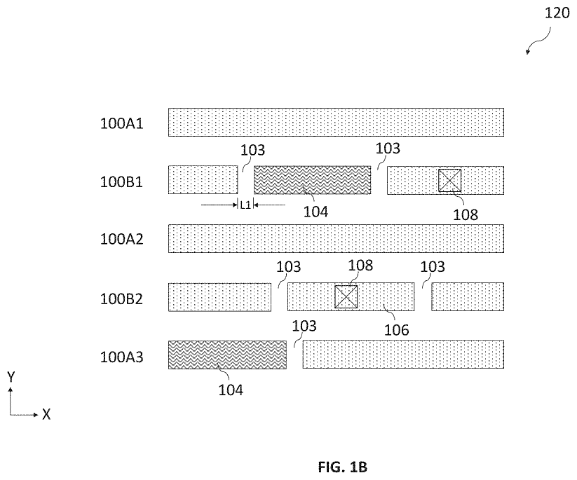

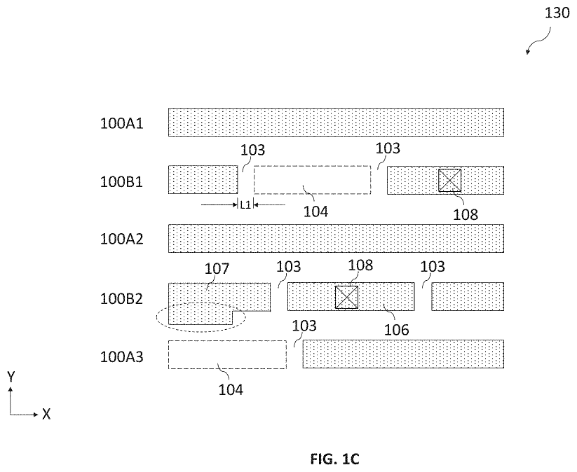

In semiconductor integrated circuit (IC) design, as ICs continue to scale down, the number of metal interconnects in an interconnect layer over the device area of an IC are increasing. To allow more metal interconnects to be formed over the device area, metal interconnects can be formed using a multi-patterning process. In a multi-patterning process, at least two batches of metal interconnects are patterned consecutively. To avoid short circuits between these metal interconnects formed by the multi-patterning process, the pattern of metal interconnects of a later batch can be formed by, e.g., a self-alignment double patterning (SADP) process using the pattern of metal interconnects of an earlier batch. The metal interconnects formed can include redundant metal portions (also referred to as floating metal portions), e.g., portions of the metal interconnects that are functionless and have no electrical connection to other parts in the device area. These redundant metal portions may increase parasitic capacitance of the ICs, causing the ICs to slow down. As will be explained further below in FIGS. 1A-1C, to reduce parasitic capacitance in ICs, one way is to electrically disconnect the redundant metal portions from the ICs or to remove the redundant metal portions. That is, the redundant metal portions can be electrically disconnected or removed from the circuit layout during circuit layout design process and the circuit layout can be subsequently transferred into an inter-metal dielectric (IMD) layer or an interlayer dielectric (ILD) layer during IC fabrication process. As a result of electrical disconnection, redundant metal portions remain their physical presence in the circuit layout, which still contributes additional parasitic capacitance in the circuit. On the other hand, as a result of removing redundant metal portions before the self-alignment process, the remaining portions of the metal interconnects (e.g., active metal portions) may not have sufficient length for the self-alignment process, causing misalignment of metal interconnects in the subsequent IC fabrication process or formation of undesired structures of metal interconnects. Such misalignment or formation of undesired structures can adversely affect the uniformity of critical dimensions (CDs) (e.g., dimensions of the smallest geometrical features) of the circuit. The non-uniformity in the CDs of the circuit can result in additional parasitic capacitance in the circuit, and consequently, the capacitance of the resultant ICs may not be reduced effectively. Also, the removal of the redundant metal portions produces empty spaces between adjacent metal interconnects, which introduces constraints on the location of vias on the active metal portions due to limitations in IC fabrication. For example, vias on active metal portions adjacent to an empty space may have to be formed at least about 15 nm away from the ends of the active metal portions due to design rules. Such constraints on via locations can limit the density of vias in the IC, which can limit the number of electrical connections between IC devices through metal interconnects and vias, thus limiting the density of IC devices.

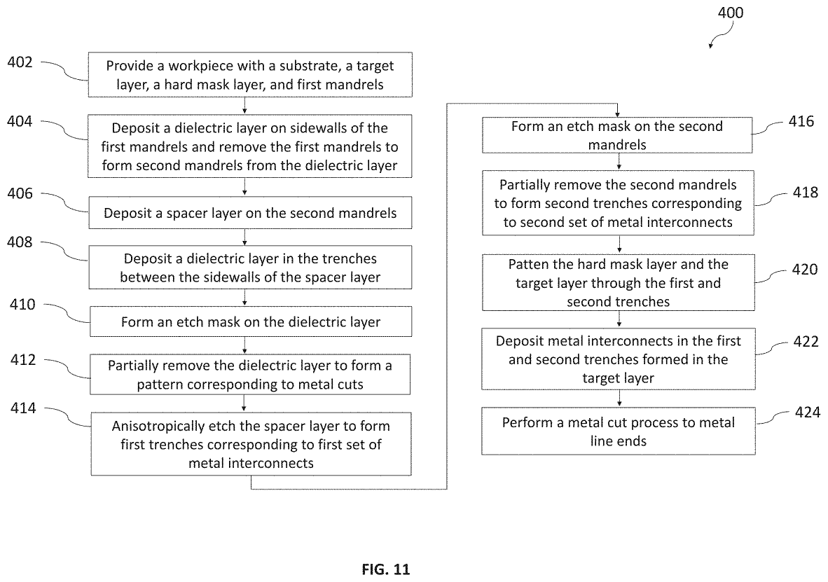

FIGS. 1A, 1B, and 1C illustrate the electrically disconnecting or the removal of floating metal portions in a layout of metal interconnects. FIG. 1A illustrates a layout 100 of interleaving metal lines 100A1-100A3 (collectively as metal lines 100A) and 100B1-100B2 (collectively as metal lines 100B) with which locations of electrical disconnections 102 are marked (in dashed lines). An electrical disconnection 102 cuts a metal line into two segments, which is also termed as a metal cut 102. A metal cut 102 can be formed by a physical metal cut process using a cut pattern during the subsequent IC fabrication process and replaced by an insulating material such as, an oxide and/or a nitride material. Alternatively, a metal cut 102 can be implemented together with the patterning of the metal lines 100A1-100A3 and 100B1-100B2 at a multi-patterning process, such as shown in an example IC fabrication process with reference to FIGS. 11-27B. The metal cuts 102 creates floating metal portions 104. The floating metal portions 104 are functionless and have no electrical connection to other parts in the device area. Notably, two adjacent metal cuts 102 do not necessarily create a floating metal portion therebetween. For example, the metal portion 106 on the metal line 100B2 is located between two metal cuts 102 and may not have electrical connections with other metal lines 100A1-100A3 and 100B1-100B2, yet still has electrical connections to other interconnect structures in overlying or underlying layers through a via 108 overlapping the metal portion 106. Therefore, the metal portion 106 is considered as an active metal portion as it functions as a landing pad for the via 108. FIG. 1B illustrates a layout 120 of the metal lines 100A1-100A3 and 100B1-100B2 after the electrical disconnecting of floating metal portions 104. FIG. 1C illustrates a layout 120 of the metal lines 100A1-100A3 and 100B1-100B2 after the removal of floating metal portions 104.

Still referring to FIG. 1A, the metal lines 100A1-100A3 and 100B1-100B2 can be arranged along a Y-axis (e.g., the vertical direction) and can extend lengthwise along an X-axis (e.g., the horizontal direction). The metal interconnects 100A1-100A3 can be patterned by a first patterning process, and the metal interconnects 100B1-100B2 can be patterned by a second patterning process following the first patterning process. Patterning process can refer to an IC patterning process using, for example, lithography, etching, and/or deposition processes. Patterns of the metal interconnect layouts discussed herein can be made on an IMD layer (or an ILD layer) using a lithography process on masking layers (shown in an example IC fabrication process with reference to FIGS. 11-27B). These patterns can be subsequently transferred to the IMD layer using etching processes, followed by deposition processes to form an interconnect layer with the layout of metal interconnects. The interconnect layer can be formed on active devices (e.g., MOSFETs) with some metal portions (e.g., active metal portions) of metal interconnects electrically connected to contact structures (e.g., source/drain contact structures and/or gate contact structures) of the active devices through vias. The vias 108 in FIG. 1A can represent vias underlying or overlying the interconnect layer. Some of the metal interconnects (e.g., metal line 100A1) can be electrically connected to VDD (e.g., power supply) or GND (e.g., ground). The metal lines 100B1-100B2 can be patterned through a self-aligning process based on the patterns of the metal lines 100A1-100A3. Metal can be deposited in trenches transferred from the patterns of the metal lines 100A1-100A3 and 100B1-100B2 to form the metal lines 100A1-100A3 and 100B1-100B2, and vias can be formed before and/or after the formation of the metal lines 100A1-100A3 and 100B1-100B2. In the illustrated embodiment, the metal lines 100A1-100A3 and 100B1-100B2 are in an M0 layer with a uniform pattern. Alternatively, the metal lines 100A1-100A3 and 100B1-100B2 may be in an M1 layer or other metal interconnect layers Mx. The term “uniform pattern” in the present disclosure refers to that each metal line has the same width (denoted as “W”) and is separated from an adjacent metal line for the same distance (denoted as “D”) in a layout area of interests. In some embodiments, the width W is in a range from about 1 nm to about 100 nm and the distance D is in a range from about 1 nm to about 1000 nm. A uniform pattern facilitates a manufacturing flow to achieve better process control with the increasing density of metal interconnects in the layout area, particularly in lower metal interconnect layers. It is noted that three (3) metal lines 100A1-100A3 and two (2) meta lines 100B1-100B2 are alternately arranged as illustrated in figures, which is for illustrative purposes only and not intended to be limiting beyond what is specifically recited in the claims. It can be appreciated that the metal interconnect layout may include any number of metal lines 100A corresponding to the first patterning process and any number of metal lines 100B corresponding to the second patterning process.

Referring to FIG. 1B, FIG. 1B illustrates a layout 120 with the metal lines 100A1-100A3 and 100B1-100B2 of the layout 100 after the metal cuts 102 are inserted with insulating portions 103 during a circuit layout design process and/or an IC patterning process. The floating metal portions 104 are retained in the layout 120. In the illustrated embodiment as in FIG. 1B, the metal portions at locations of the metal cuts 102 are removed for at least a minimum length (denoted as “L1”) equal to one gate pitch. One gate pitch can be defined as a distance between centerlines of two adjacent gates of the IC. The gate pitch can be referred to as a poly pitch or polysilicon gate pitch. The gate pitch can also be referred to as contact poly pitch (CPP). So, one gate pitch can be referred to as 1 CPP. That is, the distance L1 between two opposing ends of the metal line segments after the insulating portions 103 are inserted equals to or is larger than 1 CPP. Since the floating metal portions 104 remain in the layout 120 as running parallel to neighboring metal lines, large redundant parasitic capacitance remains between two parallel metal lines. The parasitic capacitance may cause circuit speed degradation.

Referring to FIG. 1C, FIG. 1C illustrates a layout 130 after the removal of the floating metal portions 104 of the layout 100 during a circuit layout design process and/or an IC patterning process. The remaining metal portions after the removal of the floating metal portions 104 can be referred to as active metal portions. In the illustrated embodiment as in FIG. 1C, the floating metal portions 104 in the metal lines 100A1-100A3 (such as the floating metal portion 104 in the metal line 100A3) are removed during the first patterning process. The patterns of the metal lines 100A1-100A3 are for self-aligning of the metal lines 100B1-100B2 during the second patterning process. Because substantial portions of the patterns of the metal lines 100A1-110A3 have been removed, when the active metal portions of the metal lines 100B1-110B2 are formed by the self-alignment process based on the patterns of the remaining active metal portions of the metal lines 100A1-100A3, the patterns of the active metal portions of the metal lines 100B1-100B2 can deviate from the alignment of the original design. For example, the active metal portion 107 can include an excessive portion (as circled by the dashed lines) of metal due to the removal of the floating metal portion 104 of the metal line 100A3. The excessive portion of metal can alter the CD of the IC and the CD uniformity of the circuit can be impaired. As a result, the non-uniform CD can result in additional parasitic capacitance in the circuit, and consequently, lower the speed of the resultant IC.

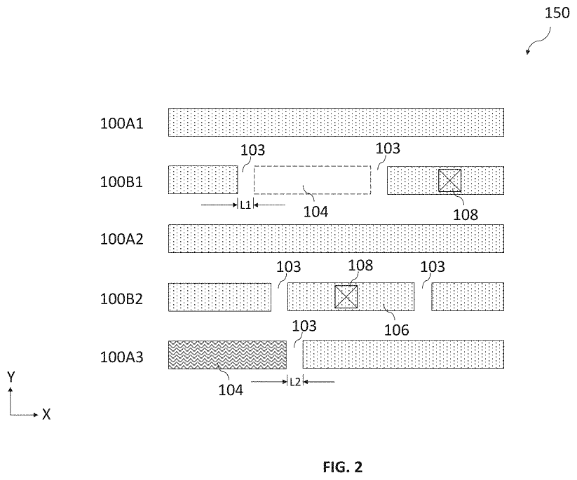

Reference is now made to FIG. 2. FIG. 2 illustrates a layout 150 after the removal of the floating metal portions 104 of the layout 100 during a circuit layout design process and/or an IC patterning process. One difference between the layout 150 and the layout 130 as illustrated in FIG. 1C is that the floating metal portions in the metal lines 100A1-100A3 are retained. For example, the floating metal portion 104 in the metal line 100A3 is retained. The floating metal portion 104 in the metal line 100A3 can be deposited with the same electrically conductive material (e.g., a metal) that forms the active metal portions in the metal lines 100A1-100A3 in a same metal deposition process. By forming an insulating portion 103 to electrically disconnect the floating metal portion 104 in the metal line 100A3 from other active metal portions and yet by allowing the floating metal portion 104 in the metal line 100A3 to retain, more redundant metal portions in the metal lines 100A3 are remained to keep the metal line 100A3 sufficiently long. Sufficiently long metal lines 100A1-100A3 allow the active metal portions in the metal lines 100B1-100B2 to better self-align during the second patterning process. The removal of the floating metal portion 104 in the metal lines 100B1-100B2 still effectively reduce the parasitic capacitance of the IC.

Generally speaking, the disclosed patterns of metal interconnects can include different sets of patterns for forming metal interconnects in sequential patterning processes. For example, the metal lines 100A1-100A3 are referred to as a first set of metal interconnects, and the metal lines 100B1-100B2 are referred to as a second set of metal interconnects. The first set of metal interconnects and the second set of metal interconnects can be formed in two-step multi-patterning process in a subsequent IC fabrication process. More sets of metal interconnects can also be patterned by placing more patterns (e.g., a third set and/or a fourth set) of metal interconnects in the circuit layout (not shown). The active metal portions of the first set of metal interconnects are referred to as the first active metal portions, and the active metal portions of the second set of metal interconnects are referred to as the second active metal portions. The redundant metal portions (or floating metal portions) of the first set of metal interconnects are referred to as the first redundant metal portions, and the redundant metal portions of the second set of metal interconnects are referred to as second redundant metal portions. In the present disclosure, the terms such as “first” and “second” are used merely for distinguishing different elements and are not intended to indicate any differences (e.g., in functions) amongst the elements. The second redundant metal portions are removed from the layout, while the first redundant metal portions are retained. By retaining the first redundant metal portions, the first set of metal interconnects remain sufficiently long to allow the second active metal portions to self-align efficiently based on the first set of metal interconnects. Meanwhile, the second redundant metal portions are removed from the second set of metal interconnects, which effectively reduces the parasitic capacitance between adjacent metal interconnects. Also, the disclosed improvement in the layout 150 helps to maintain CD uniformity of the circuit and to further reduce the parasitic capacitance of the IC, which can help to increase the device speed of the IC and reduce the power consumption of the IC. Thus, device performance can be improved. In some embodiments, by using the disclosed methods in the back end of the line (BEOL) stage of IC fabrication, capacitance of the IC can be reduced by about 10% to 50% and the speed of the IC can be increased by about 1% to about 10% compared to circuits having metal interconnects patterned with all the redundant metal portions retained as described in FIG. 1B.

Still referring to FIG. 2, in a design process to form the circuit layout 150, the metal lines 100A1-100A3 and 100B1-100B2 without metal cuts 102 (placeholder for insulating portions 103) can first be placed using an EDA tool. The locations and the lengths of the metal cuts 102 can then be determined (e.g., by the EDA tool). Redundant metal portions can then be electrically disconnected/removed from the corresponding active metal portions by insulating portions 103. In some embodiments, the metal portions at locations of the metal cuts 102 are removed for at least a minimum length L1 equal to 1 CPP (i.e., L1≥1 CPP) to comply with the design rules in the EDA tool. In some embodiments, the design rules in an EDA tool can be modified to allow the metal cuts 102 to have a smaller length to exist in a circuit layout as still comply with a design rule check (DRC) to be taken to tape-out (e.g., the final result of design process for ICs before they are manufactured, specifically the point at which the graphic for the photomask of the ICs is sent for fabrication). Particularly, in some embodiments, design rules that allow metal cuts 102 in the first set of metal interconnects (e.g., the metal lines 100A1-100A3) to have a smaller minimum length (denoted as “L2”) can be added/supplemented into the existing design rules of an EDA tool that forms the circuit layout. For example, the minimum length L2 in the metal lines 100A1-100A3 may be in a range from about 0.4 CPP to about 1 CPP. That is the minimum length L2 in the metal lines 100A1-100A3 may be smaller than the minimum length L1 in the metal lines 100B1-100B2. The smaller minimum length L2 further ensures sufficient lengths of the metal lines 100A1-100A3 for a better self-align of the metal lines 100B1-100B2 during the second patterning process.

FIGS. 3 and 4 illustrate intermediate circuit layouts 150-1 and 150-2 to form circuit layout 150 in FIG. 2, according to some embodiments. Referring to FIG. 3, in the intermediate circuit layout 150-1, after the locations of the metal cuts 102 are determined, the floating metal portions 104 are identified. Corresponding to the floating metal portions 104 in the metal lines 100B1-100B2, a metal cut 105 are marked. Since the vias 108 on adjacent active metal portions in the metal lines 100B1-100B2 may be sufficiently away, the length of the floating metal portion 104 in the metal lines 100B1-100B2 can be further expanded, allowing more redundant metal to be removed and thus less parasitic capacitance. A distance between a via 108 on active metal portions adjacent to an empty space may have to be formed at least a minimum distance (denoted as “L3”) away from the ends of the active metal portions due to design rules. Under some design rules, the minimum distance L3 may be in a range from about 1 CPP to about 2 CPP. For each via 108 on the metal lines 100B1-100B2, an extra metal cut 109 may be added between the initial metal cut 102 and the via 108 to reduce the distance between the via 108 and the respective end of the active metal portion to substantially the minimum distance L3. In other words, the operation reduces a length of the landing pad 106 to about 2 times of the minimum distance L3 plus the length of a via 108, which in turn increases amount of the redundant metal portions to be removed. Referring to FIG. 4, the metal cut 102, 105, and 109 on the metal lines 100B1-100B2 are merged into one larger metal cut 110, while the metal cut 102 on the metal lines 100A1-100A3 may remain the length or adversely shrink to a smaller minimum length L2 as discussed above. The metal cut 110, which corresponds to a floating metal portion, has a length at least 2 times the minimum length L1 (2 CPP).

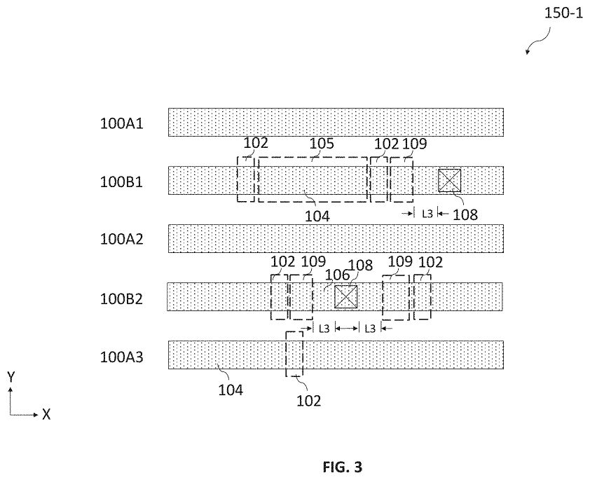

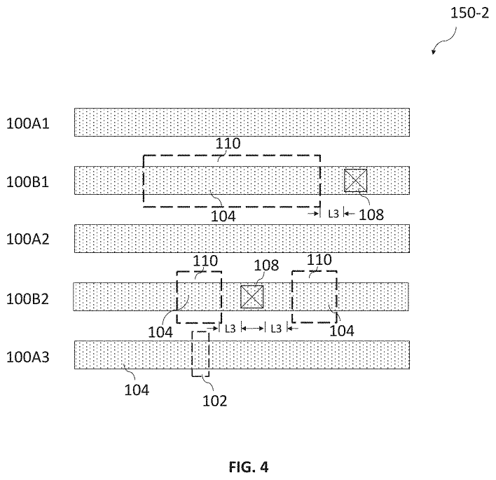

FIGS. 5 and 6 illustrate alternative intermediate circuit layouts 150-3 and 150-4 to form circuit layout 150 in FIG. 2, according to some embodiments. Referring to FIG. 5, in some embodiments, locations of the vias 108 can be adjusted. One reason to relocate a via 108 is that the distance between the via 108 and an initial metal cut 102 may be smaller than the distance between the via 108 and the insulating portions replacing the removed floating metal portions 104. For example, a minimum distance (denoted as “L4”) between the via 108 and an initial metal cut 102 may be about 0.5 CPP to about 1 CPP, which is smaller than the minimum distance L3 that is about 1 CPP to about 2 CPP. Such constraints on the via locations can be because the active metal portion ends formed facing the insulating portions are more rounded than the active metal portion ends formed facing the small metal cuts. Therefore, by relocating a via 108 towards one metal cut 102 allows one larger metal cut 109 to be added on the other side of the via 108. In other words, such operation reduces a length of the landing pad 106 to about a sum of the minimum distances L3, L4, and the length of a via 108, which is even smaller than the example illustrated in FIG. 3 and in turn further increases amount of the redundant metal portions to be removed. Referring to FIG. 4, the metal cut 102, 105, and 109 on the metal lines 1001-100B2 are merged into one larger metal cut 110, while the metal cut 102 on the metal lines 100A1-100A3 may remain the length or adversely shrink to a smaller minimum length L2 as discussed above.

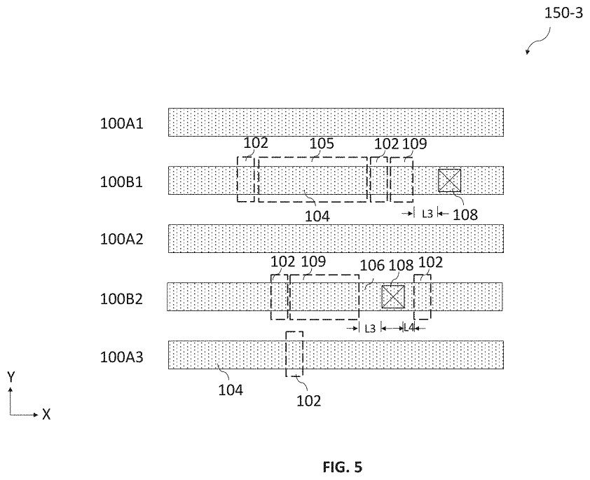

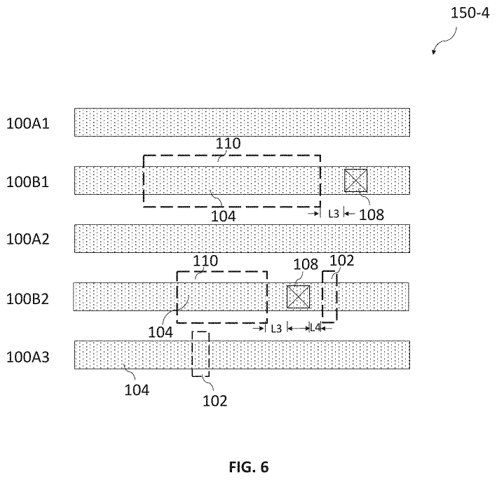

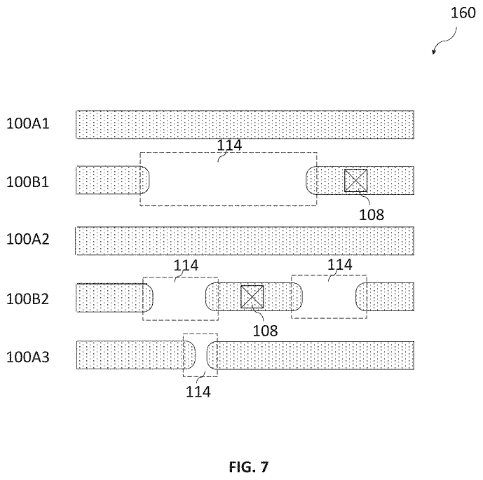

FIG. 7 illustrates a layout 160 that more closely resembles the physical shape of the end portions of the metal lines 100A1-100A3 and 100B1-100B2 after the multi-patterning process. The rounded profile of the end portions of the metal lines is mainly due to resolution limitation in lithography during the multi-patterning process. An extra metal cut mask providing patterns of the metal cuts 114 may further be applied for an extra metal cut process to sharpen the edges of the end portions of the metal lines 100A1-100A3 and 100B1-100B2. The sharpened edges further reduce parasitic capacitance between metal lines.

FIG. 8 is a flow diagram of a method 200 for removing and/or electrically disconnecting redundant metal portions in a circuit layout, according to some embodiments. In some embodiments, operations of method 200 can be performed in different orders. Variations of method 200 should also be within the scope of the present disclosure. At operation 202, a circuit layout is scanned to determine a first set of metal interconnects and a second set of metal interconnects. The first set of metal interconnects corresponds to a first patterning process in a multi-patterning process, such as a self-aligned double patterning (SADP) process. The second set of metal interconnects corresponds to a second patterning process in the multi-patterning process. At operation 204, metal cuts and redundant metal portions that need to be removed and/or electrically disconnected are determined. In some embodiments, it can be determined (e.g., by an EDA tool) that the metal portions not connected with vias are redundant metal portions (e.g., redundant metal portions 104). The locations of the redundant metal portions can be those described with reference to FIGS. 1A-7. At operation 206, vias on the second set of metal interconnects are relocated according to locations of the metal cuts. The relocation of the vias allows maximizing the redundant metal portions to be removed. At operation 208, sizes of the redundant metal portions on the second set of metal interconnects are adjusted according to the locations of the vias. The adjustment enlarges the sizes of the redundant metal portions. At operation 210, sizes of the initial metal cuts on the first set of metal interconnects are adjusted. The adjustment reduces the sizes of the initial metal cuts. At operation 212, the circuit layout is updated with the removal of the redundant metal portions on the second set of metal interconnects and the metal cuts on the first and second sets of metal interconnects. Active metal portions can be retained in the metal interconnects of the circuit layout. In some embodiments, the removal of redundant portions can include replacement of the redundant metal portions with dielectric isolation materials. The arrangement of the resulting metal interconnects can be in accordance with DRC rules. In some embodiments, before redundant metal portions can be removed and/or electrically disconnected, it is determined whether it is possible to remove and/or electrically disconnect the redundant metal portions without violating the spacing rules and/or DRC rules. In some embodiments, DRC rules can include the spacing rules of the metal cut optimization structure described above.

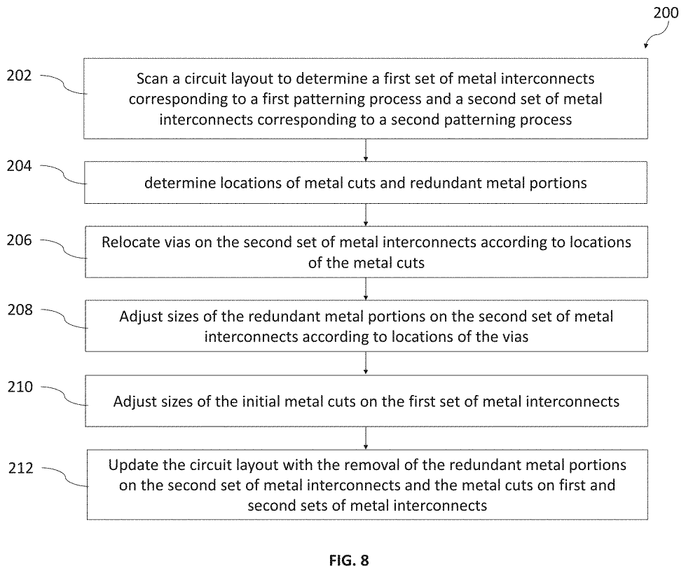

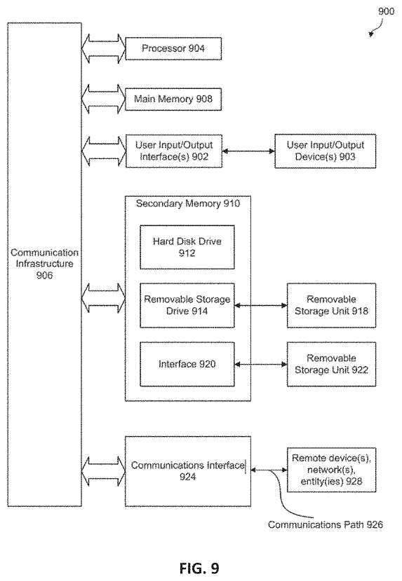

FIG. 9 is an illustration of an example computer system 900 in which various embodiments of the present disclosure can be implemented, according to some embodiments. The computer system 900 can be any well-known computer capable of performing the functions and operations described herein. For example, and without limitation, the computer system 900 can be capable of determining redundant metal portions and metal interconnects to be optimized and placing metal cuts/dielectric materials at desired locations in the circuit layout, for example, an EDA tool. The computer system 900 can be used, for example, to execute one or more operations in method 200 and/or method 300, which describes an example method for placing metal cuts/dielectric materials for disconnecting/reducing redundant metal portions in a layout area.

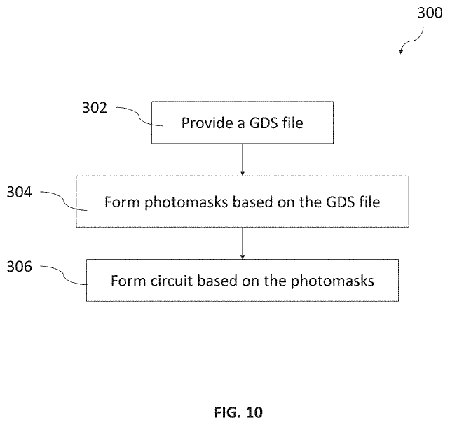

The computer system 900 includes one or more processors (also called central processing units, or CPUs), such as a processor 904. The processor 904 is connected to a communication infrastructure or bus 906. The computer system 900 also includes input/output device(s) 903, such as monitors, keyboards, pointing devices, etc., that communicate with communication infrastructure or bus 906 through input/output interface(s) 902. An EDA tool can receive instructions to implement functions and operations described herein—e.g., method 200 of FIG. 8 and/or method 300 of FIG. 10 (described below)—via input/output device(s) 903. The computer system 900 also includes a main or primary memory 908, such as random access memory (RAM). The main memory 908 can include one or more levels of cache. The main memory 908 has stored therein control logic (e.g., computer software) and/or data. In some embodiments, the control logic (e.g., computer software) and/or data can include one or more of the operations described above with respect to method 200 of FIG. 8 and/or method 300 of FIG. 10.

The computer system 900 can also include one or more secondary storage devices or memory 910. The secondary memory 910 can include, for example, a hard disk drive 912 and/or a removable storage device or drive 914. The removable storage drive 914 can be a floppy disk drive, a magnetic tape drive, a compact disk drive, an optical storage device, tape backup device, and/or any other storage device/drive.

The removable storage drive 914 can interact with a removable storage unit 918. The removable storage unit 918 includes a computer usable or readable storage device having stored thereon computer software (control logic) and/or data. The removable storage unit 918 can be a floppy disk, magnetic tape, compact disk, DVD, optical storage disk, and/any other computer data storage device. The removable storage drive 914 reads from and/or writes to removable the storage unit 918 in a well-known manner.

According to some embodiments, the secondary memory 910 can include other means, instrumentalities or other approaches for allowing computer programs and/or other instructions and/or data to be accessed by the computer system 900. Such means, instrumentalities or other approaches can include, for example, a removable storage unit 922 and an interface 920. Examples of the removable storage unit 922 and the interface 920 can include a program cartridge and cartridge interface (such as that found in video game devices), a removable memory chip (such as an EPROM or PROM) and associated socket, a memory stick and USB port, a memory card and associated memory card slot, and/or any other removable storage unit and associated interface. In some embodiments, the secondary memory 910, the removable storage unit 918, and/or the removable storage unit 922 can include one or more of the operations described above with respect to method 200 of FIG. 8 and/or method 300 of FIG. 10.

The computer system 900 can further include a communication or network interface 924. The communication interface 924 enables the computer system 900 to communicate and interact with any combination of remote devices, remote networks, remote entities, etc. (individually and collectively referenced by reference number 928). For example, the communication interface 924 can allow computer system 900 to communicate with remote devices 928 over communications path 926, which can be wired and/or wireless, and which can include any combination of LANs, WANs, the Internet, etc. Control logic and/or data can be transmitted to and from the computer system 900 via communication path 926.

The operations in the preceding embodiments can be implemented in a wide variety of configurations and architectures. Therefore, some or all of the operations in the preceding embodiments—e.g., method 200 of FIG. 8 and method 300 of FIG. 10 (described below)—can be performed in hardware, in software or both. In some embodiments, a tangible apparatus or article of manufacture comprising a tangible computer useable or readable medium having control logic (software) stored thereon is also referred to herein as a computer program product or program storage device. This includes, but is not limited to, the computer system 900, the main memory 908, the secondary memory 910 and the removable storage units 918 and 922, as well as tangible articles of manufacture embodying any combination of the foregoing. Such control logic, when executed by one or more data processing devices (such as the computer system 900), causes such data processing devices to operate as described herein. In some embodiments, the computer system 900 is installed with software to perform operations in the manufacturing of photomasks and circuits, as illustrated in method 300 of FIG. 10. In some embodiments, the computer system 900 includes hardware/equipment for the manufacturing of photomasks and circuit fabrication. For example, the hardware/equipment can be connected to or be part of element 928 (remote device(s), network(s), entity(ies) 928) of the computer system 900.

FIG. 10 is a flow diagram of a method 300 for circuit fabrication, according to some embodiments. In some embodiments, the method 300 may be used to form circuit having circuit layout such as layout 100, 120, 130, 150, and/or 160. In some embodiments, operations/steps of the method 300 can be performed in a different order. Variations of the method 300 should also be within the scope of the present disclosure. In operation 302, a GDS file is provided. The GDS file can be generated by an EDA tool and include metal interconnects optimized based on the present disclosure. The operation depicted in 302 can be performed by, for example, an EDA tool that operates on a computer system, such as the computer system 900 described above. In operation 304, photomasks are formed based on the GDS file. In some embodiments, the GDS file provided in operation 302 is taken to a tape-out operation to generate photomasks for fabricating one or more integrated circuits. In some embodiments, a circuit layout included in the GDS file can be read and transferred onto a quartz or glass substrate to form opaque patterns that correspond to the circuit layout. The opaque patterns can be made of, for example, chromium or other suitable metals. The operation 304 can be performed by a photomask manufacturer, where the circuit layout is read using a suitable software tool (e.g., an EDA tool) and the circuit layout is transferred onto a substrate using a suitable printing/deposition tool. The photomasks reflect the circuit layout/features included in the GDS file. In operation 306, one or more circuits are formed based on the photomasks generated in operation 304. In some embodiments, the photomasks are used to form patterns/structures of the circuit contained in the GDS file. In some embodiments, various fabrication tools (e.g., photolithography equipment, deposition equipment, and etching equipment) are used to form features of the one or more circuits.

FIG. 11 is a flow diagram of a method 400 for fabricating an interconnect layer from a layout of metal interconnects, such as described with reference to FIGS. 1A-7, according to some embodiments. The method 400 is merely an example and is not intended to limit the present disclosure to what is explicitly illustrated in the method. Additional steps may be provided before, during and after the respective method, and some steps described can be replaced, eliminated, or moved around for additional embodiments of the respective method. Not all steps are described herein in detail for reasons of simplicity. The method 400 is described below in conjunction with FIGS. 12A-27B, which illustrate top views and respective cross-sectional views along A—A line of a workpiece 500 at different stages of fabrication according to embodiments of the method 400.

Referring to FIGS. 11 and 12A-12B, the method 400 includes a block 402 where a workpiece 500 is provided. The workpiece 500 is to make into a semiconductor device through operations of the method 400. The workpiece 500 may include a semiconductor substrate 502 comprising silicon or other semiconductor materials and may be covered by an insulating layer, for example. The semiconductor substrate 502 may also include other active components or circuits, not shown. The semiconductor substrate 502 may comprise silicon oxide over single-crystal silicon, for example. The semiconductor substrate 502 may include other conductive layers or other semiconductor elements, e.g., transistors, diodes, etc. Compound semiconductors, GaAs, InP, Si/Ge, or SiC, as examples, may be used in place of silicon. The workpiece 500 may comprise a silicon-on-insulator (SOI) or a germanium-on-insulator (GOI) substrate, as examples.

The workpiece 500 also includes an insulating layer 504 deposited or formed over the substrate 502. The insulating layer 504 comprises an insulating material layer in some embodiments. Throughout the description, the insulating layer 504 may be referred to as a target layer, which is to be etched an in which a target pattern including, for example, trenches for filling conductive material, is to be formed. In some embodiments, the target layer 504 that is to be etched is an IMD layer or an ILD layer, which is formed of a dielectric material having a dielectric constant (k value) lower than about 3.8. In alternative embodiments, the target layer 504 is formed of a dielectric layer including silicon oxide, BSG, PSG, BPSG, FSG, TEOS oxide, or a combination thereof. The target layer 504 may be formed by a spin-on process, a chemical vapor deposition (CVD), or plasma enhanced CVD (PECVD), or another suitable method.

The workpiece 500 also includes a hard mask layer 506 formed over the target layer 504 and an etch stop layer 508 formed over the hard mask layer 506. The hard mask layer 506 may be a single layer or a multi-layer structure. The hard mask layer 506 comprises TiN, TiO, amorphous Si, SiN, or combinations or multiple layers thereof in some embodiments, for example. The hard mask layer 506 may be deposited using physical vapor deposition (PVD), atomic layer deposition (ALD), or CVD, as examples. Alternatively, the hard mask 506 may comprise other materials and dimensions and may be formed using other methods. The etch stop layer 508 comprises a material with an etch selectivity to a subsequently deposited material layer, such as the mandrel layer 510. The etch stop layer 508 etches at a slower rate than the mandrel layer 510 etches during an etch process for the mandrel layer 510, for example. The etch stop layer 508 may comprise SiN, SiON, nitride-doped carbide, or oxide-doped carbide, as examples. The etch stop layer 508 may be deposited by PVD, CVD, or another suitable method. Alternatively, the etch stop layer 508 may comprise other materials and may be formed using other methods. The etch stop layer 508 protects the underlying layers from subsequent etching damages.

The workpiece 500 also includes a mandrel layer 510 formed over the etch stop layer 508. The mandrel layer 510 may be a single layer or a multi-layer structure. The mandrel layer 510 may include polysilicon or amorphous silicon. In some embodiments, the mandrel layer 510 includes a material that has a high etching selectivity compared with the etch stop layer 508. The mandrel layer 510 may be formed by PVD, CVD, or another suitable method. A patterning process is performed on the mandrel layer 510 to form mandrel patterns with openings 512, such that the etch stop layer 508 is exposed therefrom. The patterning process may be a photolithography process, which may include forming a resist layer on the mandrel layer 510, exposing the resist by a lithography exposure process, performing a post-exposure bake process, developing the photoresist layer to form the patterned photoresist layer that exposes part of the mandrel layer 510, patterning the mandrel layer 510, and finally removing the patterned resist layer. The lithography process may be alternatively replaced by other suitable techniques, such as e-beam writing, ion-beam writing, maskless patterning or molecular printing. The mandrels in the patterned mandrel layer 510 are also denoted as the first mandrels 510.

Referring to FIGS. 11 and 13A-14B, the method 400 includes a block 404 where a dielectric layer 514 is deposited on sidewalls of the mandrels 510. The dielectric layer 514 may include a dielectric material including metal nitride (such as AlN, TiN, or TaN), metal oxide (such as HfO, AlOx, TiOx), or the like. The dielectric layer 514 may be formed by a PVD process (such as RFPVD), an ALD process, a CVD process, or another suitable method. The dielectric layer 514 is subsequently anisotropically etched to remove the horizontal portions, while the vertical portions of the dielectric layer 514 remain on sidewalls of the first mandrels 510. In the illustrated embodiment, the size of the openings 512 is selected such that the dielectric layer 514 still fills up the openings 512 between adjacent first mandrels 510 after the etching, as shown in FIGS. 13A-13B. Subsequently, the first mandrels 510 are removed in a selective etching process, as shown in FIGS. 14A-14B. In some embodiments, the selective etching process includes a dry etching process (such as a plasma etching) or a wet etching process. At conclusion of operations at the block 404, the remaining portions of the dielectric layer 514 are also referred to as the second mandrels 514.

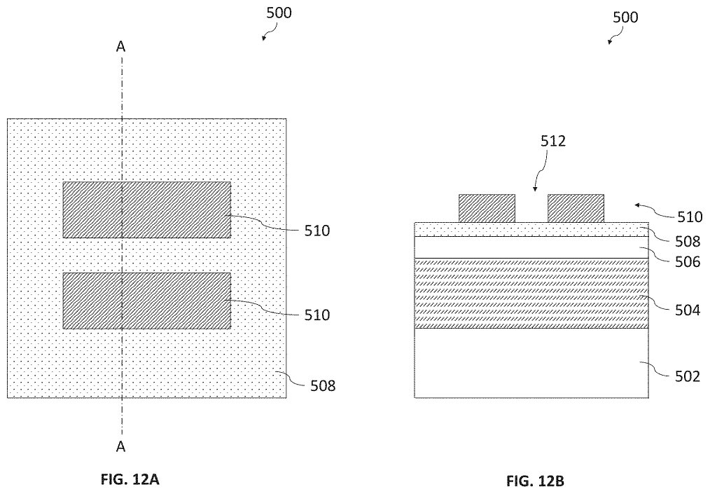

Referring to FIGS. 11 and 15A-15B, the method 400 includes a block 406 where a spacer layer 516 is deposited on the second mandrels 514 and the etch stop layer 508. The spacer layer 516 may be conformally formed on sidewalls and top surfaces of the second mandrels 514. The spacer layer 516 may include a dielectric material including metal nitride (such as AlN, TiN, or TaN), metal oxide (such as HfO, AlOx, TiOx), or the like. In these cases, the selected material of the spacer layer 516 is different from that of the second mandrels 514, such that the spacer layer 516 has a higher etching selectivity with the second mandrels 514.

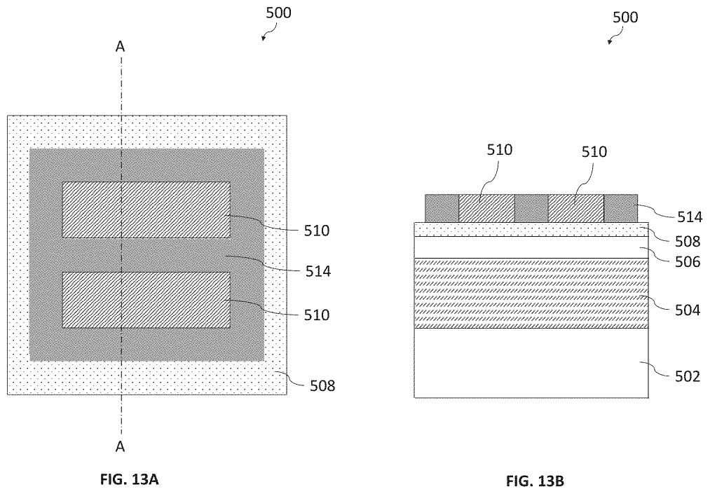

Referring to FIGS. 11 and 16A-16B, the method 400 includes a block 408 where a dielectric layer 518 is formed in the trenches between the sidewalls of the spacer layer 516. The dielectric layer 518 may comprise SiN, SiON, nitride-doped carbide, or oxide-doped carbide, as examples. The dielectric layer 518 may be deposited by PVD, ALD, CVD, or another suitable method. The dielectric layer 518 may first be deposited covering sidewalls and top surfaces of the spacer layer 516. Subsequently, excessive portions of the dielectric layer 518 and the spacer layer 516 are removed from over the top surfaces of the dielectric layer 514 using a chemical-mechanical polish (CMP) process, such that the top surfaces of the second mandrels 514 are exposed.

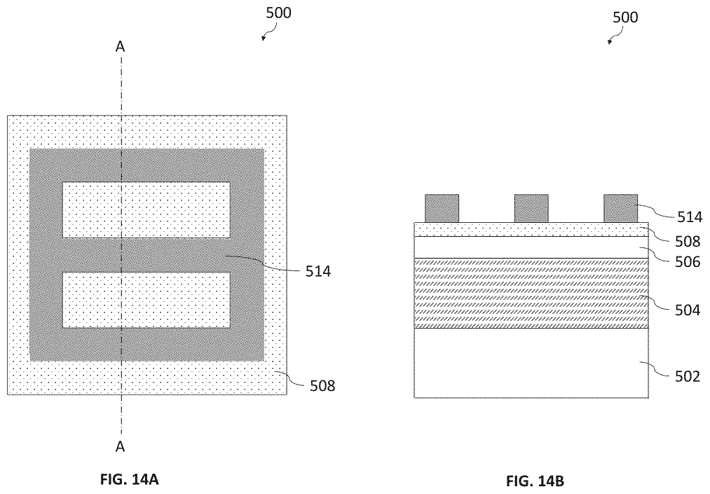

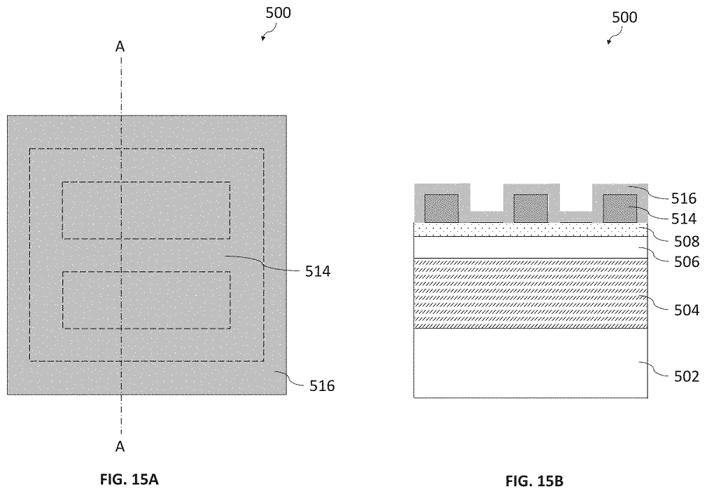

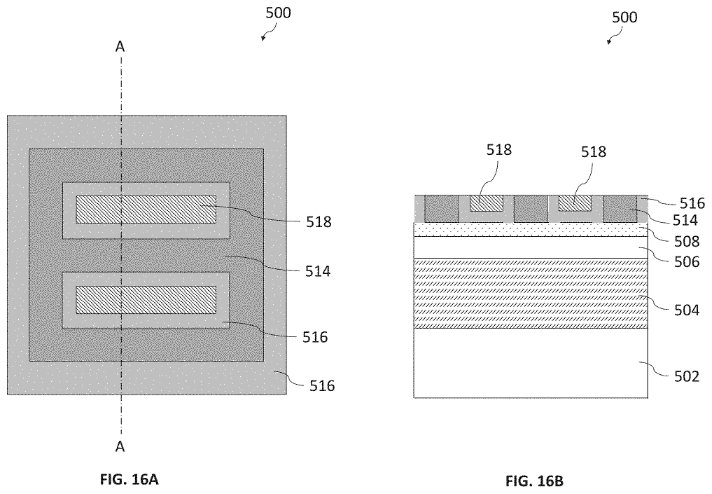

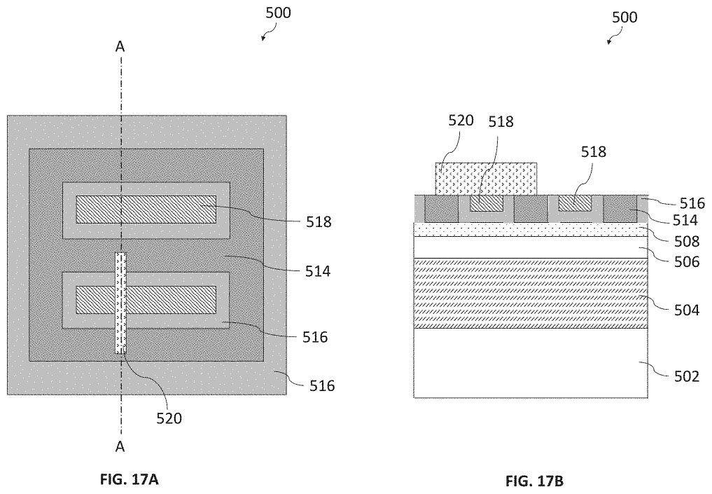

Referring to FIGS. 11 and 17A-17B, the method 400 includes a block 410 where an etch mask 520 is formed on the dielectric layer 514. The etch mask 520 extends across a portion of the dielectric layer 514 and also covers a portion of the top surfaces of the spacer layer 516 and the second mandrels 514. In some embodiments, the etch mask 520 is a photoresist layer. The etch mask 520 may be formed by depositing a photoresist layer, exposing the photoresist layer by a lithography exposure process, performing a post-exposure bake process, and developing the photoresist layer.

Referring to FIGS. 11 and 18A-18B, the method 400 includes a block 412 where the dielectric layer 518 is partially removed in an etching process. The etching process includes a dry etching process (such as a plasma etching) or a wet etching process. The portion of the dielectric layer 518 protected under the etch mask 520 remains. The remaining portion of the dielectric layer 518 is self-aligned between the sidewalls of the spacer layer 516, reducing resolution requirement of the lithography process. After the etching process, the etch mask 520 is removed, such as in a photoresist ashing process.

Referring to FIGS. 11 and 19A-19B, the method 400 includes a block 414 where the spacer layer 516 is anisotropically etched to remove the horizontal portions of the spacer layer 516, while the vertical portions of the spacer layer 516 remain on sidewalls of the second mandrels 514. The vertical portions of the spacer layer 516 are hereinafter also referred to as spacers 516. A portion of the spacer layer 516 under the dielectric layer 518 also remains from the anisotropic etching. The removal of the horizontal portions of the spacer layer 516 forms first trenches 522 that expose the top surface of the etch stop layer 508. The pattern of the first trenches 522 corresponds to the first set of metal interconnects (e.g., metal lines 100A1-100A3 in FIGS. 1A-7). The pattern of the remaining portions of the dielectric layer 518 corresponds to the metal cuts on the first set of metal interconnects (e.g., the metal cuts 102 on the metal lines 100A1-100A3 in FIGS. 1A-7).

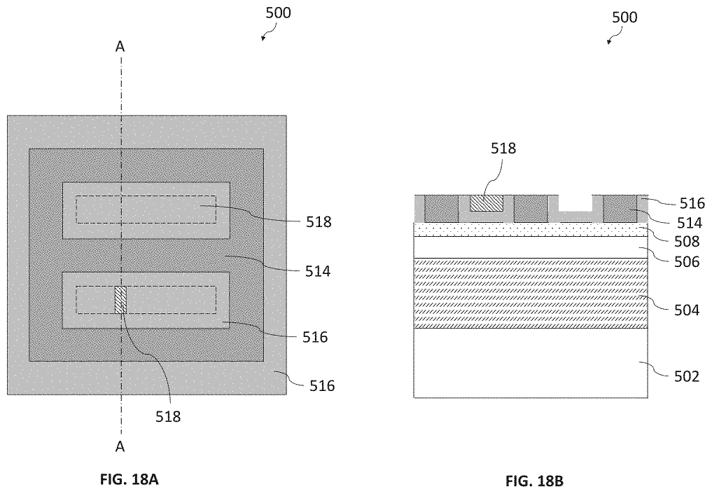

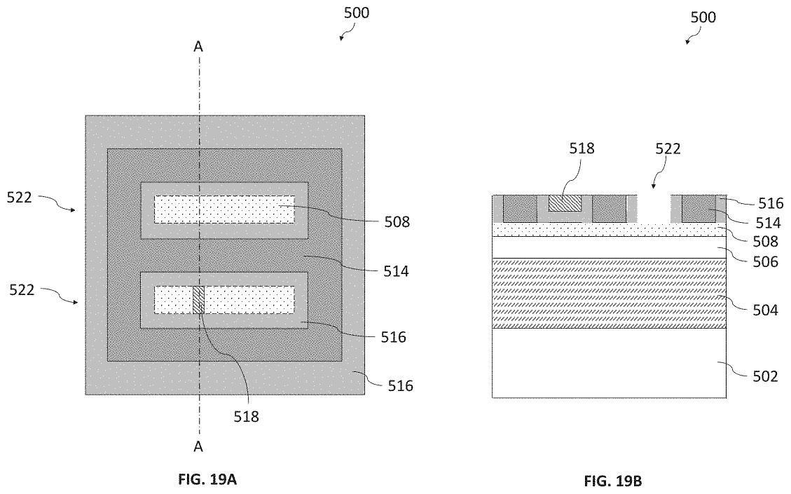

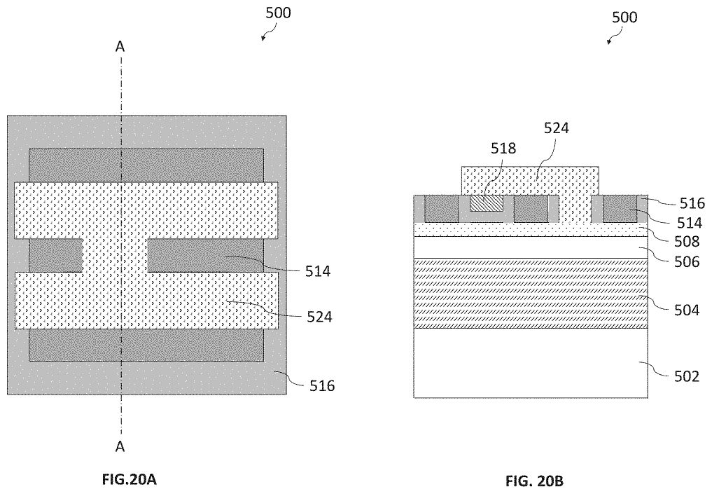

Referring to FIGS. 11 and 20A-20B, the method 400 includes a block 416 where an etch mask 524 is formed filling the first trenches 522 and covering a portion of the second mandrels 514. The etch mask 524 also covers the remaining portions of the dielectric layer 518. In some embodiments, the etch mask 524 is a photoresist layer. The etch mask 524 may be formed by depositing a photoresist layer, exposing the photoresist layer by a lithography exposure process, performing a post-exposure bake process, and developing the photoresist layer.

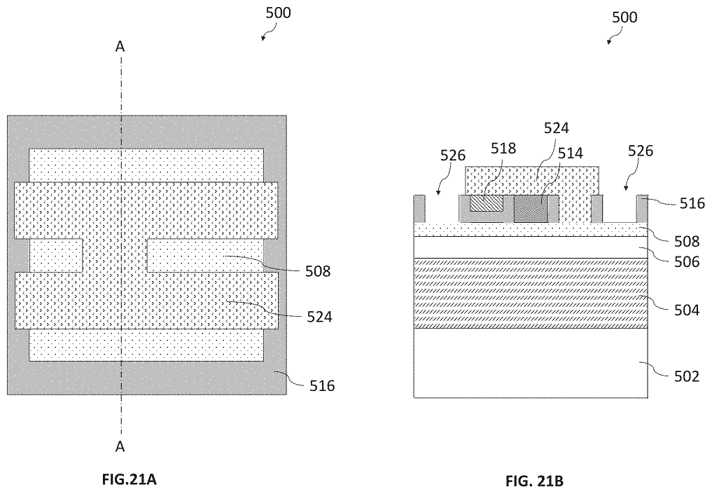

Referring to FIGS. 11 and 21A-22B, the method 400 includes a block 418 where the second mandrels 514 are partially removed in an etching process. The etching process includes a dry etching process (such as a plasma etching) or a wet etching process. The removal of the second mandrels 514 forms second trenches 526 that expose the top surface of the etch stop layer 508. The portion of the second mandrels 514 protected under the etch mask 524 is remained, as shown in FIGS. 21A-21B. The remaining portions of the dielectric layer 514 is self-aligned between adjacent spacers 516, reducing resolution requirement of the lithography process. After the etching process, the etch mask 524 is removed, such as in a photoresist ashing process, as shown in FIGS. 22A-22B. The pattern of the second trenches 526 corresponds to the second set of metal interconnects (e.g., lines 100B1-100B2 in FIGS. 1A-7). The pattern of the remaining portions of the second mandrels 514 overlying the second trenches 526 corresponds to the metal cuts on the second set of metal interconnects (e.g., the metal cuts 102 and/or 110 on the metal lines 100B1-100B2 in FIGS. 1A-7).

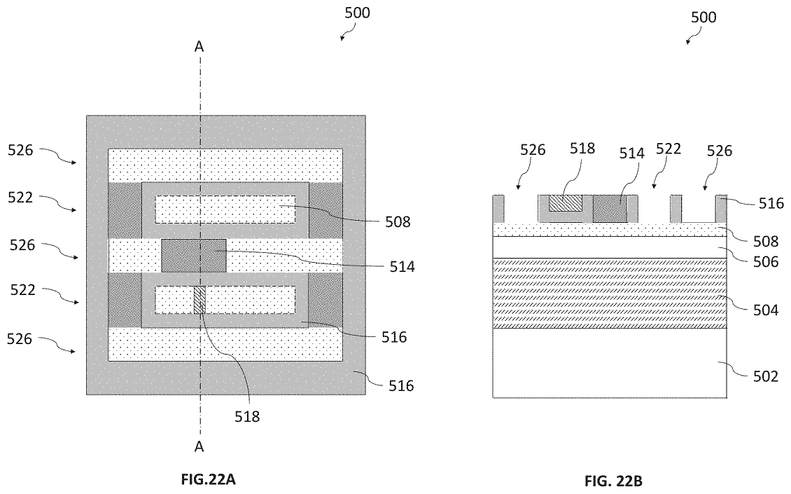

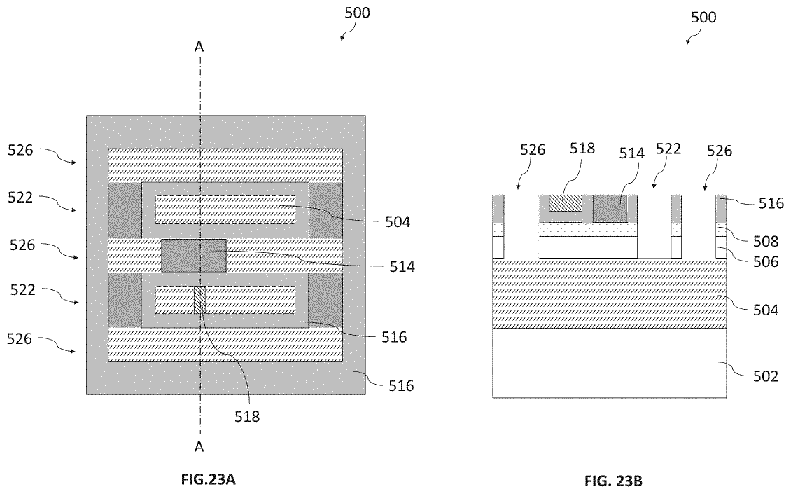

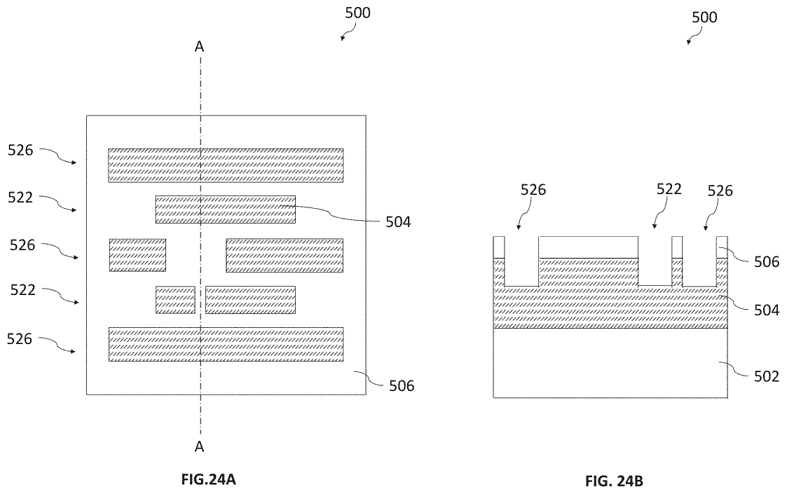

Referring to FIGS. 11 and 23A-24B, the method 400 includes a block 420 where the etch stop layer 508 and the hard mask layer 506 are patterned by using the spacers 516 and the remaining portions of the second mandrels 514 as an etch mask in an etching process. The etching process includes a dry etching process (such as a plasma etching) or a wet etching process. The etching process extends the first trenches 522 and the second trenches 526 downwardly through the etch stop layer 508 and the hard mask layer 506, such as shown in FIGS. 23A-23B. Subsequently, the spacers 516 and the remaining portions of the dielectric layer 514, and the etch stop layer 508 may be removed. Operations at the block 418 also includes patterning the target layer 504 using the patterned hard mask layer 506 as an etch mask in an etching process. The etching process includes a dry etching process (such as a plasma etching) or a wet etching process. The etching process extends the first trenches 522 and the second trenches 526 downwardly through the hard mask layer 506 and into the target layer 504, such as shown in FIGS. 24A-24B.

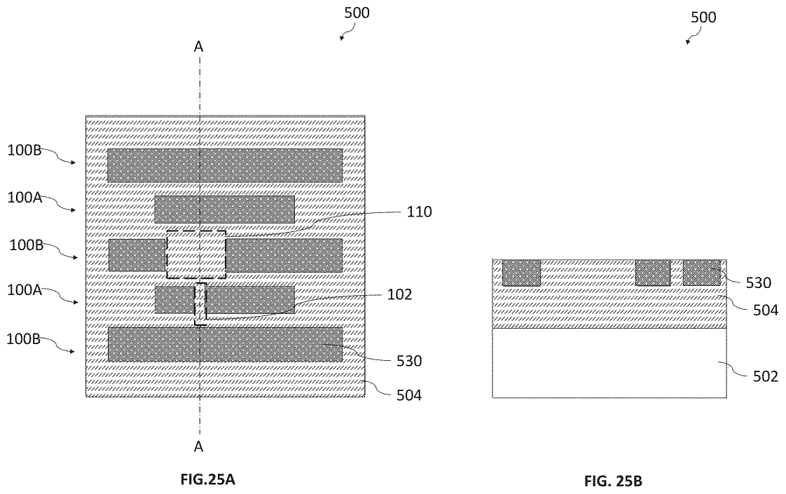

Referring to FIGS. 11 and 25A-25B, the method 400 includes a block 422 where metal lines 530 are formed in the first trenches 522 and the second trenches 526 of the target layer 504. In some embodiments, forming the metal lines 530 includes forming a barrier layer (not shown) in the first trenches 522 and the second trenches 526, forming a seed layer (also not shown) over the barrier layer, and forming conductive material (such as titanium (Ti), tantalum (Ta), nickel (Ni), tungsten (W), cobalt (Co), copper (Cu), and/or other suitable materials) over the seed layer. The conductive material may be plated onto the seed layer in some embodiments. An electro-chemical plating (ECP) process may be used, as an example. Alternatively, the conductive material may be formed using other methods. Alternatively, a barrier layer or seed layer may not be included. The excessive portions of the conductive material is then removed from over the top surface of the target layer 504 using a CMP process. The hard mask layer 506 may also be removed in the CMP process. The metal lines 530 formed in the first trenches 522 correspond to the first set of metal interconnects, such as the metal lines 100A in FIGS. 1A-7. The metal lines 530 formed in the second trenches 526 correspond to the second set of metal interconnects, such as the metal lines 100B in FIGS. 1A-7. The gap between adjacent metal line segments of a metal line 100A corresponds to a metal cut 102 in the FIGS. 1A-7. The gap between adjacent metal line segments of a metal line 100B corresponds to a metal cut 110 in the FIGS. 1A-7, which includes the removal of a floating metal portion.

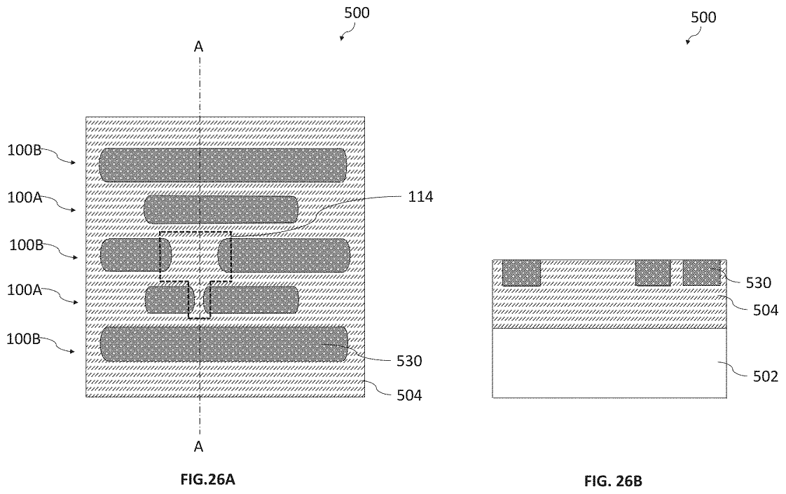

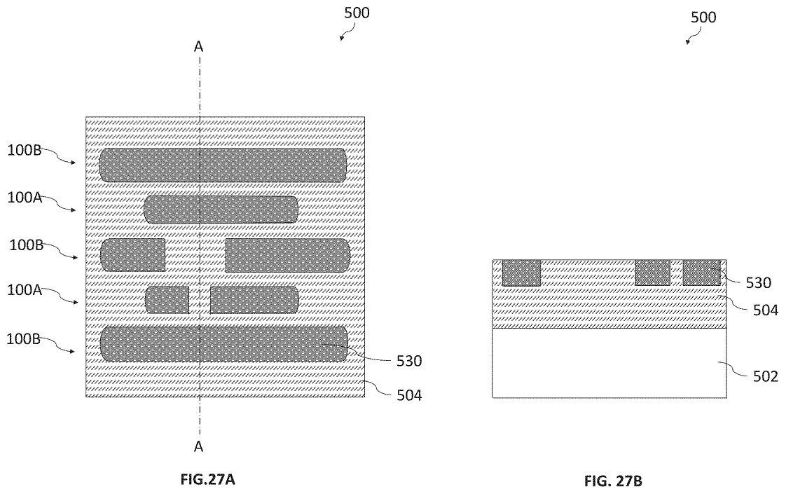

Referring to FIGS. 11 and 26A-27B, the method 400 may further include a block 424 where an extra metal cut process is performed to sharpen edges of the end portions of the metal lines 530. FIG. 26A illustrates a top view of the metal lines 530 that more closely resembles the physical shape of the end portions after the multi-patterning process. The rounded profile of the end portions of the metal lines is mainly due to resolution limitation in lithography during the multi-patterning process. An extra metal cut mask comprising a pattern of metal cuts 114 (FIG. 7) may be applied as an etch mask in a metal cut process to sharpen the edges of the end portions of the metal lines 530. A dielectric isolation material may be filled in the portions where the metal lines 530 are removed in the metal cut process. A top view of the resultant metal lines 530 after the extra metal cut process is shown in FIG. 27A. The sharpened edges further reduce parasitic capacitance between the metal lines.

Although not intended to be limiting, one or more embodiments of the present disclosure provide many benefits to a semiconductor device and the formation thereof. Embodiments of the present disclosure describe methods to remove and/or electrically disconnect redundant metal portions of metal interconnects to form active metal portions of metal interconnects in a circuit layout to reduce parasitic capacitance of an IC and improve the speed of the IC. Further, the disclosed methods help to maintain CD uniformity of the circuit. The methods can be performed at the design stage of the circuit layout for the IC. In some embodiments, by using the disclosed methods in the back end of the line (BEOL) stage of IC fabrication, capacitance of the circuit can be reduced by up to about 50% and the speed of the circuit can be increased by about 1% to about 10% compared to circuits having redundant metal portions remained.

In one exemplary aspect, the present disclosure is directed to a method. The method includes receiving a layout that includes a plurality of metal interconnects, identifying a first set of metal interconnects from the metal interconnects corresponding to a first patterning process and a second set of metal interconnects from the metal interconnects corresponding to a second patterning process, identifying a first set of floating metal portions in the first set of metal interconnects and a second set of floating metal portions in the second set of metal interconnects, and removing the second set of floating metal portions from the layout, while the first set of floating metal portions remains in the layout. In some embodiments, the method further includes providing the layout with removal of the second set of floating metal portions for fabricating a photomask. In some embodiments, the metal interconnects are in a metal 0 (M0) interconnect layer. In some embodiments, the metal interconnects have a uniform pattern. In some embodiments, the method further includes locating metal cuts on the first and second sets of metal interconnects, the identifying of the first and second sets of floating metal portions being based on locations of the metal cuts. In some embodiments, the method further includes merging at least two metal cuts on the second sets of metal interconnects to form a merged metal cut. In some embodiments, the merged metal cut has a length of least 2 contact poly pitch (CPP). In some embodiments, the method further includes reducing a length of the metal cuts on the first set of metal interconnects. In some embodiments, the method further includes locating vias on the first and second sets of metal interconnects, the identifying of the second set of floating metal portions being based on locations of the vias on the second set of metal interconnects. In some embodiments, the method further includes relocating at least one of the vias on the second set of metal interconnects to reduce a distance between the via and a metal cut on the second set of metal interconnects.

In another exemplary aspect, the present disclosure is directed to a method. The method includes scanning a layout to determine first metal interconnects corresponding to a first patterning process and second metal interconnects corresponding to a second patterning process, locating metal cuts and vias on the first and second metal interconnects, merging at least two metal cuts on the second metal interconnects to form an enlarged metal cut on the second metal interconnects, removing portions of the first and second metal interconnects under the metal cuts and the enlarged metal cut from the layout, and providing the layout with removal of the portions of the first and second metal interconnects for fabricating a photomask. In some embodiments, the method further includes forming an extra metal cut pattern to sharpen edges of the first and second metal interconnects. In some embodiments, the method further includes adjusting locations of the vias on the second metal interconnects according to locations of the metal cuts on the second metal interconnects. In some embodiments, the adjusting of the location of the vias includes reducing a minimum distance between a via and an edge of an adjacent metal cut. In some embodiments, the method further includes reducing a length of the metal cuts on the first metal interconnects. In some embodiments, the reduced length of the metal cuts is from about 0.4 contact poly pitch (CPP) to about 1 CPP.

In another exemplary aspect, the present disclosure is directed to a method of manufacturing a semiconductor device. The method includes forming mandrels on a substrate, depositing a spacer layer on sidewalls and top surfaces of the mandrels, wherein sidewalls of the spacer layer define first trenches therebetween, depositing a dielectric layer in the first trenches, patterning the dielectric layer, thereby defining a pattern of first metal cuts, patterning the mandrels to define second trenches and a pattern of second metal cuts, etching the substrate through the first and second trenches, thereby extending the first and second trenches into the substrate, and depositing a conductive material in the first and second trenches, thereby forming metal interconnects in the substrate. In some embodiments, the second metal cuts have a larger size than the first metal cuts. In some embodiments, the method further includes after the patterning of the dielectric layer, anisotropically etching the spacer layer, thereby forming spacers on the sidewalls of the mandrels. In some embodiments, the method further includes after the depositing of the conductive material, performing a metal cut process to end portions of the metal interconnects.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method, comprising:
receiving a layout that includes a plurality of metal interconnects;
identifying a first set of metal interconnects from the metal interconnects corresponding to a first patterning process and a second set of metal interconnects from the metal interconnects corresponding to a second patterning process;
identifying a first set of floating metal portions in the first set of metal interconnects and a second set of floating metal portions in the second set of metal interconnects; and
removing the second set of floating metal portions from the layout, while the first set of floating metal portions remains in the layout.

2. The method of claim 1, further comprising:
providing the layout with removal of the second set of floating metal portions for fabricating a photomask.

3. The method of claim 1, wherein the metal interconnects are in a metal 0 (M0) interconnect layer.

4. The method of claim 1, wherein the metal interconnects have a uniform pattern.

5. The method of claim 1, further comprising:
locating metal cuts on the first and second sets of metal interconnects, wherein the identifying of the first and second sets of floating metal portions is based on locations of the metal cuts.

6. The method of claim 5, further comprising:
merging at least two metal cuts on the second sets of metal interconnects to form a merged metal cut.

7. The method of claim 6, wherein the merged metal cut has a length of least 2 contact poly pitch (CPP).

8. The method of claim 5, further comprising:
reducing a length of the metal cuts on the first set of metal interconnects.

9. The method of claim 1, further comprising:
locating vias on the first and second sets of metal interconnects, wherein the identifying of the second set of floating metal portions is based on locations of the vias on the second set of metal interconnects.

10. The method of claim 9, further comprising:
relocating at least one of the vias on the second set of metal interconnects to reduce a distance between the via and a metal cut on the second set of metal interconnects.

11. A method, comprising:
scanning a layout to determine first metal interconnects corresponding to a first patterning process and second metal interconnects corresponding to a second patterning process;
locating metal cuts and vias on the first and second metal interconnects;
merging at least two metal cuts on the second metal interconnects to form an enlarged metal cut on the second metal interconnects;
removing portions of the first and second metal interconnects under the metal cuts and the enlarged metal cut from the layout; and
providing the layout with removal of the portions of the first and second metal interconnects for fabricating a photomask.

12. The method of claim 11, further comprising:
forming an extra metal cut pattern to sharpen edges of the first and second metal interconnects.

13. The method of claim 11, further comprising:
adjusting locations of the vias on the second metal interconnects according to locations of the metal cuts on the second metal interconnects.

14. The method of claim 13, wherein the adjusting of the location of the vias includes reducing a minimum distance between a via and an edge of an adjacent metal cut.

15. The method of claim 11, further comprising:
reducing a length of the metal cuts on the first metal interconnects.

16. The method of claim 15, wherein the reduced length of the metal cuts is from about 0.4 contact poly pitch (CPP) to about 1 CPP.

17. A method of manufacturing a semiconductor device, comprising:
forming mandrels on a substrate;
depositing a spacer layer on sidewalls and top surfaces of the mandrels, wherein sidewalls of the spacer layer define first trenches therebetween;
depositing a dielectric layer in the first trenches;
patterning the dielectric layer, thereby defining a pattern of first metal cuts;
patterning the mandrels to define second trenches and a pattern of second metal cuts;
etching the substrate through the first and second trenches, thereby extending the first and second trenches into the substrate; and
depositing a conductive material in the first and second trenches, thereby forming metal interconnects in the substrate.

18. The method of claim 17, wherein the second metal cuts have a larger size than the first metal cuts.

19. The method of claim 17, further comprising:
after the patterning of the dielectric layer, anisotropically etching the spacer layer, thereby forming spacers on the sidewalls of the mandrels.

20. The method of claim 17, further comprising:
after the depositing of the conductive material, performing a metal cut process to end portions of the metal interconnects.
